(19) United States
(12) Patent Application Publication
(10) Pub. No.: US 2026/0081565 A1
(43) Pub. Date: Mar. 19, 2026

(54) SIGNAL GENERATION APPARATUS, METHOD, AND POWER AMPLIFICATION SYSTEM

(71) Applicant: Kangxi Communication Technologies (Shanghai) Co., Ltd., Shanghai (CN)

(72) Inventor: Huan ZHAO, Shanghai (CN)

(73) Assignee: Kangxi Communication Technologies (Shanghai) Co., Ltd., Shanghai (CN)

(21) Appl. No.: 19/345,076

(22) Filed: Sep. 30, 2025

Related U.S. Application Data
(63) Continuation of application No. PCT/CN2024/119215, filed on Sep. 14, 2024.

(51) Int. Cl. H03F 1/30; H03F 3/24

(52) U.S. Cl. CPC H03F 1/303; H03F 3/245; H03F 2200/451

(57) ABSTRACT

The disclosure discloses a signal generation apparatus, method, and power amplification system. The signal generation apparatus includes a compensation module and a signal amplification module. The compensation module is configured to provide at least one compensation signal. The signal amplification module is configured to amplify the compensation signal such that the amplified compensation signal matches a power amplifier. The compensation signal counteracts variations—arising over time and/or due to environmental factors—of relevant signals in the power amplifier, thereby stabilizing the output signal of the power amplifier. The compensation module operates independently of components such as a main bias circuit within the power amplifier, eliminating the need to modify the internal structure and/or parameters of the power amplifier. This configuration ensures compatibility with various types of power amplifiers and application scenarios, offering higher flexibility.

This non-provisional patent application claims priority under 35 U.S.C. § 119 from PCT Patent Application No. PCT/CN2024/119215 filed on Sep. 14, 2024, the entire content of which is incorporated herein by reference.

### TECHNICAL FIELD

The disclosure relates to the field of circuit technology, specifically to a signal generation apparatus, a signal generation method, and a power amplification system.

### BACKGROUND

A power amplifier (PA) is a critical component of radio frequency (RF) equipment, and the stability of its output signal significantly impacts the performance of the corresponding RF equipment. However, during actual operation, the output signal of a power amplifier is susceptible to environmental factors such as time and/or temperature. For example, the amplitude of the output signal of some power amplifiers may increase with rising ambient temperature. Traditional solutions often adjust the output signal of the power amplifier by reconfiguring the structure and/or parameters of the main bias circuit within the power amplifier to make its output signal tend to be stable. This adjustment solution requires modifying the structure and/or parameters inside the power amplifier (such as the main bias circuit), which has limitations.

### SUMMARY

In view of this, the disclosure provides a signal generation apparatus, a signal generation method, and a power amplification system to address the limitations of traditional solutions for stabilizing the output signal of a power amplifier.

The signal generation apparatus provided in the disclosure includes a compensation module, being independent of a main bias circuit in the power amplifier. The compensation module includes a plurality of compensation branches, and a signal amplification module, each one of the plurality of the compensation branches is respectively configured to output an upward compensation signal or a downward compensation signal; the output signals of these branches are combined to form a compensation signal that counteracts variations—arising over time and/or due to environmental factors—of relevant signals in the power amplifier; generation and combination of each compensation branch's output signals are determined based on the compensation requirements for possible variations in the power amplifier that may occur over time and/or due to environmental factors in corresponding application scenarios. The signal amplification module is configured to amplify the compensation signal so that the amplified compensation signal matches the power amplifier and is directly output to the main bias circuit of the power amplifier.

Optionally, the compensation module includes a reference current source, at least one current providing unit, a first resistor, the reference current source has an input terminal being configured to receive a first voltage, and an output terminal being connected to an input terminal of the signal amplification module, thus enabling the reference current source to generate a reference current. The at least one current providing unit outputs a time-varying current in at least one direction to an output terminal of the reference current source, and the time-varying current is superimposed on the reference current to form a compensation current. The first resistor is connected between the output terminal of the reference current source and a ground terminal to convert the compensation current into a compensation voltage. The at least one current providing unit includes: a first current providing unit, and/or a second current providing unit, the first current providing unit provides a first superposition current to enable the corresponding compensation current to have a downward compensation capability. The second current providing unit provides a second superposition current to enable the corresponding compensation current to have an upward compensation capability.

Optionally, the first current providing unit includes at least one pull-up current generation branch; each pull-up current generation branch includes: a first current source, a first variable capacitor, a first variable resistor, and a first MOS transistor, wherein an input terminal of the first current source is configured to receive a second voltage and connected to a first terminal of the first variable resistor; an output terminal of the first current source is respectively connected to a first terminal of the first variable capacitor and a gate of the first MOS transistor; a second terminal of the first variable capacitor is connected to a ground terminal, a source of the first MOS transistor is connected to a second terminal of the first variable resistor, and a drain of the first MOS transistor is connected to the output terminal of the reference current source.

Optionally, the first current providing unit further includes a first switch corresponding to each pull-up current branch; the first switch is connected between the drain of the first MOS transistor and the output terminal of the reference current source to control on/off status of the corresponding pull-up current branch.

Optionally, the second current providing unit includes at least one pull-down current generation branch; each pull-down current generation branch includes: a second current source, a second variable capacitor, a second variable resistor, a second MOS transistor, a third MOS transistor, and a fourth MOS transistor wherein an input terminal of the second current source is configured to receive a third voltage and is connected to a first terminal of the second variable resistor, and an output terminal of the second current source is respectively connected to a first terminal of the second variable capacitor and a gate of the second MOS transistor; a second terminal of the second variable capacitor is connected to the ground terminal; a drain of the second MOS transistor is respectively connected to a drain of the third MOS transistor, a gate of the third MOS transistor, and a gate of the fourth MOS transistor; a source of the third MOS transistor is connected to the ground terminal; a drain of the fourth MOS transistor is connected to the output terminal of the reference current source, and a source of the fourth MOS transistor is connected to the ground terminal.

Optionally, the second current providing unit further includes a second switch corresponding to each pull-down current branches; the second switch is connected between the drain of the fourth MOS transistor and the output terminal of the reference current source to control on/off status of the corresponding pull-down current branch.

Optionally, the compensation module includes a downward compensation branch and/or an upward compensation branch; the downward compensation branch is configured to provide a first time-varying voltage that decreases over time; the upward compensation branch is configured to provide a second time-varying voltage that increases over time.

Optionally, the signal generation apparatus further includes: a third switch and a fourth switch, the third switch corresponds to the downward compensation branch, the third switch is connected between an output terminal of the downward compensation branch and an input terminal of the signal amplification module to control on/off status of the downward compensation branch. The fourth switch corresponds to the upward compensation branch being connected between an output terminal of the upward compensation branch and the input terminal of the signal amplification module to control on/off status of the upward compensation branch.

Optionally, the downward compensation branch includes: a first voltage source, a second resistor, a third resistor, and a first capacitor, wherein a first terminal of the first voltage source is connected to the ground terminal, and a second terminal of the first voltage source is connected to a first terminal of the second resistor and a first terminal of the first capacitor; a second terminal of the second resistor is connected to a second terminal of the first capacitor, a first terminal of the third resistor, and the input terminal of the signal amplification module; a second terminal of the third resistor is connected to the ground terminal.

Optionally, the upward compensation branch includes: a second voltage source, a fourth resistor, a fifth resistor, a sixth resistor, and a second capacitor. Wherein a first terminal of the second voltage source is connected to the ground terminal, and a second terminal of the second voltage source is connected to a first terminal of the fourth resistor; a second terminal of the fourth resistor is connected to a first terminal of the fifth resistor, a first terminal of the second capacitor, and the input terminal of the signal amplification module; a second terminal of the fifth resistor is connected to a second terminal of the second capacitor and a first terminal of the sixth resistor; a second terminal of the sixth resistor is connected to the ground terminal.

The disclosure also provides a signal generation method, being applicable to any of the aforementioned signal generation apparatus and includes step of: obtaining compensation requirements for possible variations in the power amplifier that may occur over time and/or due to environmental factors in corresponding application scenarios; controlling generation and combination of the output signals from respective compensation branches according to the compensation requirements to form a compensation signal; amplifying the compensation signal so that the amplified compensation signal matches the power amplifier.

The disclosure also provides a power amplification system, including a power amplifier and any of the aforementioned signal generation apparatus.

In the aforementioned signal generation apparatus, method, and power amplification system of the disclosure, the compensation module can provide at least one compensation signal based on possible variations in the output signal of the power amplifier in corresponding application scenarios, so as to compensate the output signal of the power amplifier. The signal amplification module amplifies the aforementioned compensation signal, which then acts on the power amplifier. In this way, the compensation signal can counteract variations—arising over time and/or due to environmental factors—of relevant signals in the power amplifier, enabling the output signal of the power amplifier to avoid being affected by environmental factors such as time and/or temperature, thus becoming more stable. Moreover, the compensation signal provided by the compensation module can be determined based on possible variations in the power amplifier in corresponding application scenarios, and is independent of components such as the main bias circuit in the power amplifier, without the need to modify the internal structure and/or parameters of the power amplifier, and can be applied to a plurality of types of power amplifiers and various application scenarios, having higher flexibility.

### BRIEF DESCRIPTION OF THE DRAWINGS

To more clearly illustrate the technical solutions in the embodiments of the disclosure, a brief introduction to the accompanying drawings required for the description of the embodiments will be provided below. It is evident that the accompanying drawings described below are merely some embodiments of the disclosure. For those skilled in the art, other accompanying drawings can also be obtained based on these drawings without exerting creative effort.

FIG. 1 is a schematic structural diagram of a power amplification system according to an embodiment of the disclosure.

FIG. 2 is a schematic structural diagram of a power amplification system according to another embodiment of the disclosure.

FIG. 3 is a schematic structural diagram of a power amplification system according to yet another embodiment of the disclosure.

FIGS. 4a, 4b, 4c, and 4d are schematic diagrams of relevant signals according to an embodiment of the disclosure.

FIGS. 5a, 5b, and 5c are schematic diagrams of a first current providing unit according to an embodiment of the disclosure.

FIGS. 6a, 6b, and 6c are schematic diagrams of a second current providing unit according to an embodiment of the disclosure.

FIG. 7 is a schematic structural diagram of a power amplification system according to another embodiment of the disclosure.

FIGS. 8a, 8b, and 8c are schematic structural diagrams of a power amplification system according to yet another embodiment of the disclosure.

FIG. 9a is a schematic structural diagram of a power amplification system according to another embodiment of the disclosure;

FIGS. 9b and 9c are schematic diagrams of relevant signals according to an embodiment of the disclosure.

### DETAILED DESCRIPTION OF THE EMBODIMENTS

Hereinafter, the technical solutions in the embodiments of the disclosure will be described clearly and completely in conjunction with the accompanying drawings. It is apparent that the described embodiments are merely a part, rather than all, of the embodiments of the disclosure. All other embodiments obtained by those skilled in the art without exerting creative effort based on the embodiments of the disclosure fall within the scope of protection of the disclosure. Where there is no conflict, the various embodiments and their technical features described below can be combined with each other.

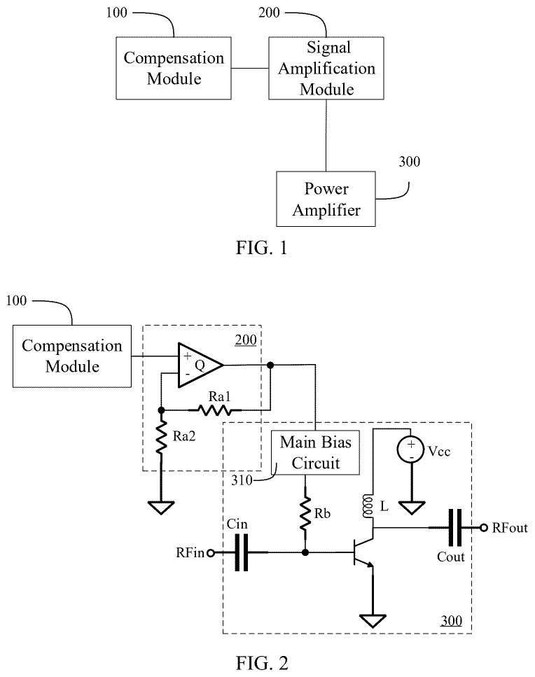

The first aspect of the disclosure provides a signal generation apparatus applied to a power amplification system to provide a control signal to a power amplifier within the power amplification system, so as to make the output signal of the power amplifier more stable. As shown in FIG. 1, the aforementioned signal generation apparatus includes a compensation module 100, and a signal amplification module 200.

The compensation module 100 is configured to provide at least one compensation signal (such as a compensation voltage or a compensation current, etc.) to compensate for possible variations in the output signal of the power amplifier 300. A quantity of compensation signal paths and compensation characteristics provided by the compensation module 100 can be determined according to the possible variations in an output signal of the power amplifier 300 in corresponding application scenarios. For example, if the output signal of the power amplifier 300 increases with rising temperature, the compensation module 100 can provide a compensation signal that gradually decreases. For another example, if the output signal of the power amplifier 300 decreases over time, the compensation module 100 can provide a compensation signal that gradually increases. For yet another example, the compensation module 100 can provide two or more compensation signals, which may be combined to counteract variations—arising over time and/or due to environmental factors—of relevant signals in the power amplifier 300. Optionally, the compensation module 100 can output the plurality of compensation signals, for example, simultaneously output a plurality of upward compensation signals (gradually increasing compensation signals), simultaneously output a plurality of downward compensation signals (gradually decreasing compensation signals), or simultaneously output at least one upward compensation signal and at least one downward compensation signal, etc. Optionally, the compensation module 100 includes a plurality of compensation branches, and each compensation branch can output one compensation signal.

The signal amplification module 200 is configured to amplify the compensation signal so that the amplified compensation signal matches the bias/drive requirements of the power amplifier 300. For example, the amplified compensation signal can directly act on components such as the main bias circuit of the power amplifier 300, so that the compensation signal can counteract variations—arising over time and/or due to environmental factors—of relevant signals in the power amplifier 300, thereby preventing the output signal of the power amplifier 300 from being affected by environmental factors such as time and/or temperature, making it more stable. Moreover, the compensation signal provided by the compensation module 100 can be determined according to possible variations in the power amplifier 300 in corresponding application scenarios, and is independent of components such as the main bias circuit in the power amplifier 300, without the need to modify the internal structure and/or parameters of the power amplifier 300, and can be applied to a plurality of types of power amplifiers and various application scenarios, having higher flexibility.

Optionally, referring to FIG. 2, the signal amplification module 200 includes an operational amplifier Q, a resistor Ra1, and a resistor Ra2. A first input terminal (non-inverting input terminal) of the operational amplifier Q serves as an input terminal of the signal amplification module 200 and is connected to an output terminal of the compensation module 100; a second input terminal (inverting input terminal) of the operational amplifier Q is respectively connected to a first terminal of the resistor Ra1 and a first terminal of the resistor Ra2; a second terminal of the resistor Ra2 is connected to a ground terminal; a second terminal of the resistor Ra1 is connected to an output terminal of the operational amplifier Q; the output terminal of the operational amplifier Q serves as an output terminal of the signal amplification module 200 and is configured to output the amplified compensation signal.

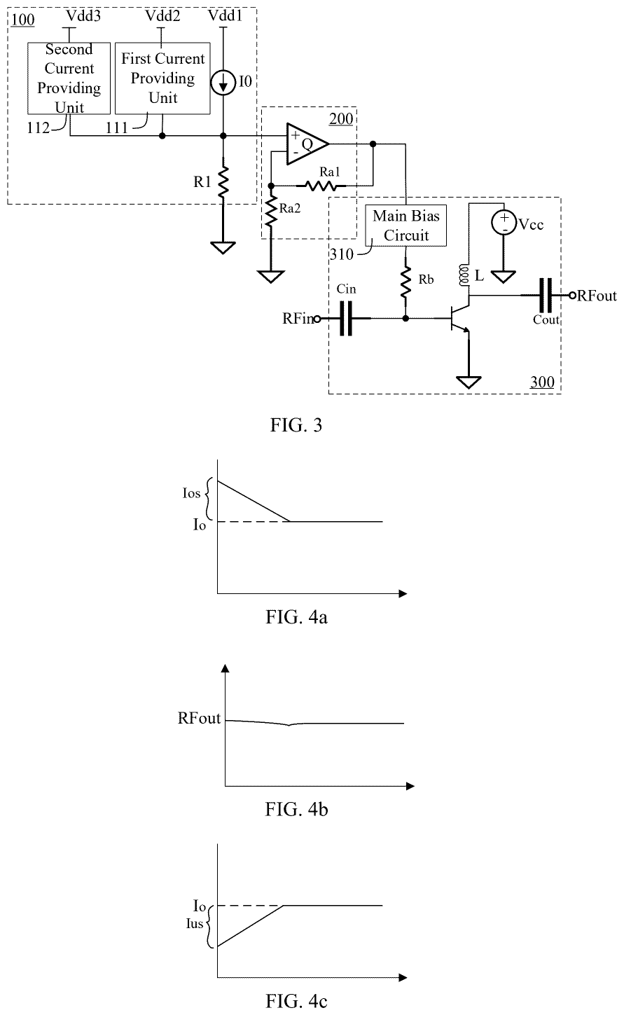

In some embodiments, referring to FIG. 3, the compensation module 100 includes a reference current source I0, a first resistor R1, and at least one current providing unit (such as a first current providing unit 111 and/or a second current providing unit 112).

An input terminal of the reference current source I0 is configured to receive a first voltage Vdd1, and an output terminal of the reference current source I0 is connected to the input terminal of the signal amplification module 200. The reference current source I0 is configured to generate a reference current, which can be a bandgap reference current.

An output terminal of each current providing unit is connected to the output terminal of the reference current source I0 and is configured to output a time-varying current in at least one direction to the output terminal of the reference current source I0 to generate a time-varying current, and the time-varying current is superimposed on the reference current to form the compensation current.

The first resistor R1 is connected between the output terminal of the reference current source I0 and the ground terminal, enabling the first resistor R1 to convert the compensation current into a compensation voltage, which serves as a compensation signal input to the signal amplification module 200. The amplified compensation voltage output by the signal amplification module 200 can act on components such as the main bias circuit of the power amplifier 300 to compensate for possible variations in the output signal of the power amplifier 300.

In some examples, as shown in FIG. 3, at least one current providing unit includes a first current providing unit 111 and/or a second current providing unit 112.

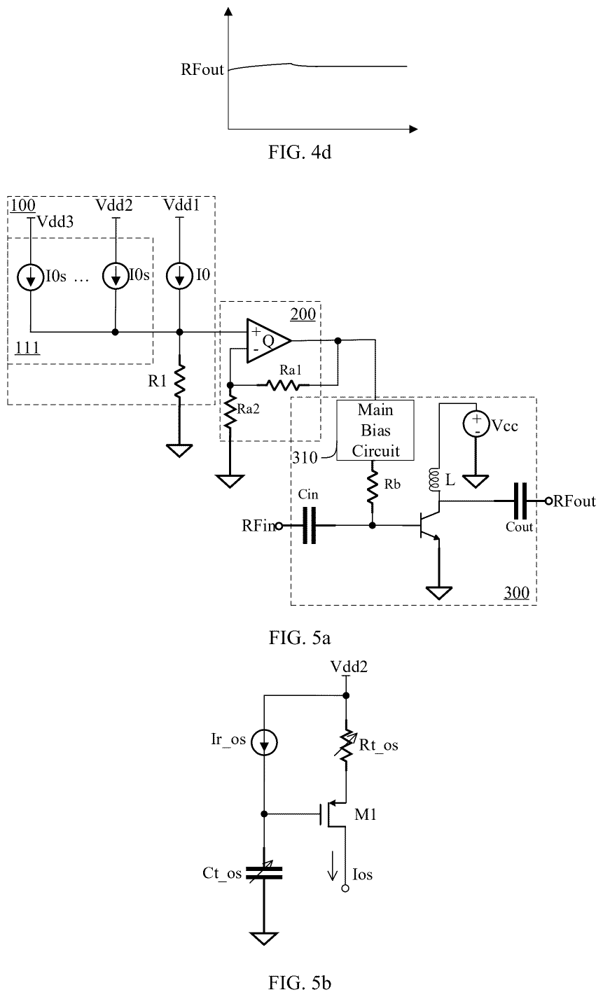

The first current providing unit 111 is configured to provide a first superposition current to enable the corresponding compensation current to have a downward compensation capability (for example, to compensate for an increase in the corresponding signal), so that the subsequent compensation voltage can compensate for an increase in the output signal of the power amplifier 300 that may occur. Specifically, the compensation current after the superposition of the first superimposed current and the reference current can be referred to in FIG. 4a. In FIG. 4a, Ios represents the first superposition current, and Io represents the reference current. The compensation current after the superposition of the first superposition current and the reference current is converted into a compensation voltage, which decreases over time, thus having a downward compensation capability and being able to compensate for an increase in relevant signals in the power amplifier 300. After being amplified by the signal amplification module 200, the compensation voltage acts on the power amplifier 300. The output signal RFout of the power amplifier 300 may be as shown in FIG. 4b. FIG. 4b shows that when the output signal of the power amplifier 300 may increase due to environmental factors, using the first current providing unit 111 to provide the first superposition current Ios and performing corresponding processing to compensate the power amplifier 300 can keep the output signal RFout of the power amplifier 300 within a stable range and improve the fidelity of the output signal RFout of the power amplifier 300.

The second current providing unit 112 is configured to provide a second superposition current to enable the corresponding compensation current to have an upward compensation capability (for example, to compensate for a decrease in the corresponding signal), so that the subsequent compensation voltage can compensate for a decrease in the output signal of the power amplifier 300 that may occur. Specifically, the compensation current after the superposition of the second superposition current and the reference current can be referred to in FIG. 4c. In FIG. 4c, Ius represents the second superimposed current, and Io represents the reference current. The compensation current generated by the superposition of Ius and Io is converted into a compensation voltage, which increases over time, thus having an upward compensation capability and being able to compensate for a decrease in relevant signals in the power amplifier 300. After being amplified by the signal amplification module 200, the compensation voltage acts on the power amplifier 300. The output signal RFout of the power amplifier 300 may be as shown in FIG. 4d. FIG. 4d shows that when the output signal of the power amplifier 300 may decrease due to environmental factors, using the second current providing unit 112 to provide the second superposition current Ius and performing corresponding processing to compensate the power amplifier 300 can keep the output signal RFout of the power amplifier 300 within a stable range and improve the fidelity of the output signal RFout of the power amplifier 300.

In some examples, as shown in FIG. 5a, the first current providing unit 111 includes at least one pull-down current generation branch I0s, and each pull-down current branch I0s is configured to generate one first superimposed current. The first superimposed current has a decreasing rate (also called a slope). Optionally, amplitudes and decreasing rates of the first superposition currents generated by the respective pull-down current generation branches I0s are different from each other, so that the decreasing rate of the first superposition current provided by the first current providing unit 111 can be adjusted by adjusting the pull-down current generation branch(es) I0s activated in the first current providing unit 111.

Specifically, referring to FIG. 5b, the pull-down current generation branch I0s includes a first current source Ir_os, a first variable capacitor Ct_os, a first variable resistor Rt_os, and a first MOS transistor M1. The first MOS transistor M1 can be a PMOS transistor. An input terminal of the first current source Ir_os is configured to receive to a second voltage Vdd2 and is connected to a first terminal of the first variable resistor Rt_os, and an output terminal of the first current source Ir_os is connected to a first terminal of the first variable capacitor Ct_os and a gate of the first MOS transistor M1. A second terminal of the first variable capacitor Ct_os is connected to a ground terminal. A source of the first MOS transistor M1 is connected to a second terminal of the first variable resistor Rt_os, and a drain of the first MOS transistor M1 is connected to the output terminal of the reference current source I0, which can serve as the output terminal of the pull-down current generation branch I0s to output one first superimposed current Ios, so that the first superposition current Ios is superimposed on the reference current. The specific parameters of the first variable capacitor Ct_os and the first variable resistor Rt_os can be set according to the required decreasing rate of the corresponding first superposition current Ios. For example, the first variable resistor Rt_os can be used to determine the maximum value of the first superposition current Ios, and the first variable capacitor Ct_os can be used to determine a time for the first superposition current Ios to change from the maximum value to the minimum value.

In the pull-down current generation branch I0s shown in FIG. 5b, when the first current source Ir_os just starts to provide current, the first MOS transistor M1 is turned on, and at this time, the first superposition current Ios reaches its maximum value. As the gate voltage of the first MOS transistor M1 increases, the first superposition current Ios gradually decreases, and the evolution of the first superposition current Ios can be observed in an output current (Ios) profile depicted in FIG. 4a. When the gate voltage of the first MOS transistor M1 rises to a certain extent, the first MOS transistor M1 is turned off, and at this time, the first superposition current Ios becomes 0. Since the current direction of the first superposition current Ios is the same as that of the reference current I0, the compensation current formed by their superposition is as shown in FIG. 4a. Optionally, the first current source Ir_os can be controlled by an enable signal. For example, a control terminal of the first current source Ir_os can receive an enable signal. When the enable signal is at a high logic level, the first current source Ir_os provides the corresponding current; when the enable signal is at a low logic level, the first current source Ir_os does not provide current.

Optionally, as shown in FIG. 5c, the first current providing unit 111 further includes a first switch S1 corresponding to each pull-down current generation branch I0s; the first switch S1 can be connected between the drain of the first MOS transistor M1 and the output terminal of the reference current source I0 to control the on/off status of the corresponding pull-down current generation branch I0s. That is, the corresponding first switch S1 is closed when the pull-down current generation branch I0s needs to be turned on, and the corresponding first switch S1 is opened when the pull-down current generation branch I0s needs to be turned off.

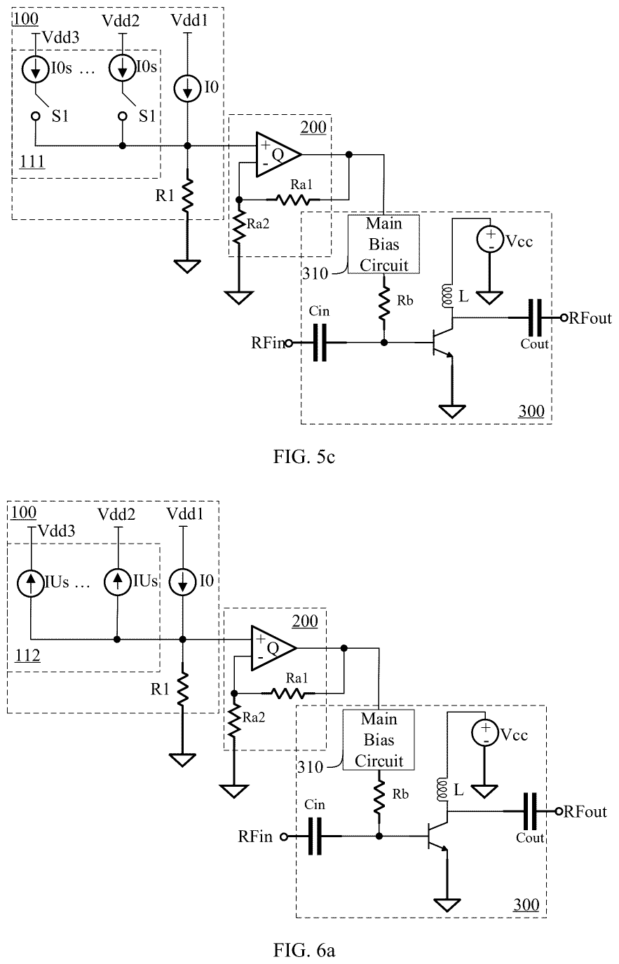

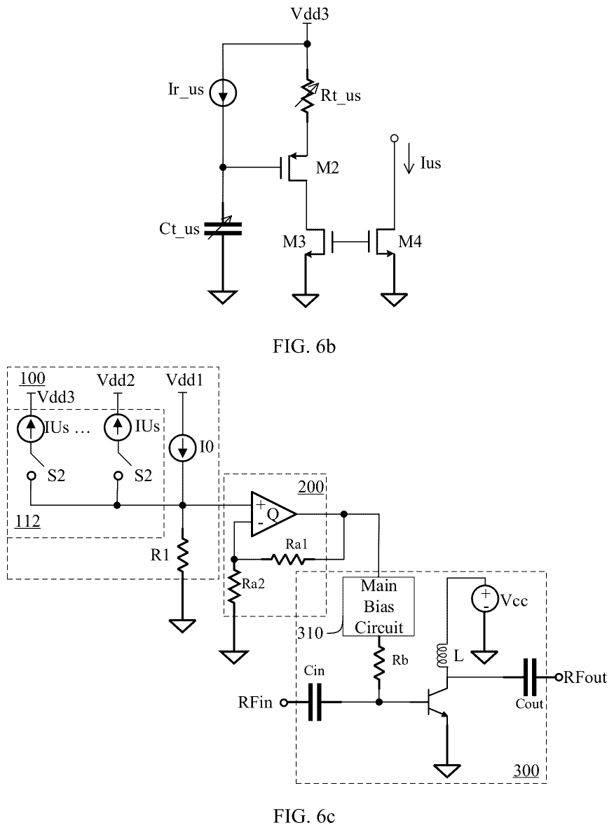

In some examples, as shown in FIG. 6a, the second current providing unit includes at least one pull-up current generation branch IUs, and each pull-up current generation branch IUs is configured to generate a second superposition current. The second superposition current has a rising rate (which can also be referred to as a slope). Optionally, the rising rates of the second superposition currents generated by the respective pull-up current generation branches IUs are different from each other. In this way, the rising rate of the second superposition current provided by the second current providing unit 112 can be adjusted by adjusting the pull-up current generation branch(es) turned on by the second current providing unit 112.

Specifically, as shown in FIG. 6b, the pull-up current generation branch IUs includes a second current source Ir_us, a second variable capacitor Ct_us, a second variable resistor Rt_us, a second MOS transistor M2, a third MOS transistor M3, and a fourth MOS transistor M4, where the second MOS transistor M2 is a PMOS transistor, and the third MOS transistor M3 and the fourth MOS transistor M4 are NMOS transistors respectively. An input terminal of the second current source Ir_us is configured to receive a third voltage Vdd3 and is connected to a first terminal of the second variable resistor Rt_us, and an output terminal of the second current source Ir_us is connected to a first terminal of the second variable capacitor Ct_us and a gate of the second MOS transistor M2; a second terminal of the second variable capacitor Ct_us is connected to the ground terminal; a drain of the second MOS transistor M2 is respectively connected to a drain of the third MOS transistor M3, a gate of the third MOS transistor M3, and a gate of the fourth MOS transistor M4; a source of the third MOS transistor M3 is connected to the ground terminal; a source of the fourth MOS transistor M4 is connected to the ground terminal, and a drain of the fourth MOS transistor M4 is connected to the output terminal of the reference current source I0, which can serve as an output terminal of the pull-up current generation branch IUs to output a second superposition current Ius, so that this second superposition current Ius is superimposed on the reference current. Specific parameters of the second variable capacitor Ct_us and the second variable resistor Rt_us can be set according to the required rising rate of the corresponding second superposition current Ius. For example, the second variable resistor Rt_us can be used to determine the maximum value of the second superposition current Ius, and the second variable capacitor Ct_us can be used to determine the time it takes for the second superposition current Ius to change from the minimum value to the maximum value.

In the pull-up current generation branch IUs shown in FIG. 6b, when the second current source Ir_us just starts to provide current, the second MOS transistor M2 is turned on, and the drain current of the second MOS transistor M2 reaches its maximum value. The third MOS transistor M3 and the fourth MOS transistor M4 form a mirror circuit, which replicates the drain current of the second MOS transistor M2 to obtain the second superposition current Ius, so the second superposition current Ius reaches its maximum value. As the gate voltage of the second MOS transistor M2 increases, the drain current of the second MOS transistor M2 gradually decreases. When the gate voltage of the second MOS transistor M2 rises to a certain extent, the second MOS transistor M2 is turned off. At this time, the drain current of the second MOS transistor M2, that is, the second superposition current Ius becomes 0. Since the current direction of the second superposition current Ius is opposite to that of the reference current I0, the compensation current formed by their superposition is shown in FIG. 4c. Optionally, the second current source Ir_us can be controlled by an enable signal. For example, the control terminal of the second current source Ir_us can receive the enable signal. When the enable signal is at a high logic level, the second current source Ir_us provides the corresponding current; when the enable signal is at a low logic level, the second current source Ir_us does not provide current.

The first voltage Vdd1, second voltage Vdd2, and third voltage Vdd3 can be the same voltage or not exactly the same voltage; for example, they can be the same voltage, or they can be three different voltages respectively, or any two of them can be the same voltage and the other one can be a different voltage.

Optionally, as shown in FIG. 6c, the second current providing unit 112 further includes a second switch S2 corresponding to each pull-up current generation branch IUs; the second switch S2 is connected between the drain of the fourth MOS transistor M4 and the output terminal of the reference current source I0 to control the on/off status of the corresponding pull-up current generation branch IUs. That is, the corresponding second switch S2 is closed when the pull-up current generation branch IUs needs to be turned on, and the corresponding second switch S2 is opened when the pull-up current generation branch IUs needs to be turned off.

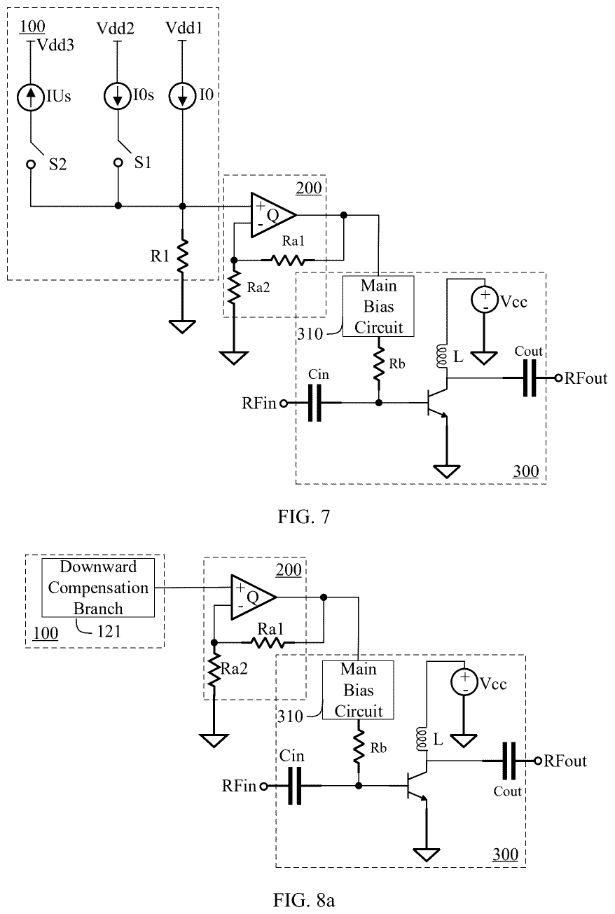

In some examples, as shown in FIG. 7, the compensation module 100 includes the first current providing unit 111 and the second current providing unit 112, that is, the compensation module 100 includes at least one pull-down current generation branch I0s, at least one pull-up current generation branch IUs, a first switch S1 corresponding to each pull-down current branch I0s, and a second switch S2 corresponding to each pull-up current generation branch IUs. In this way, when the compensation module 100 needs to provide a downward compensation voltage (which can also be referred to as a negative compensation voltage), it can close at least one first switch S1 to turn on the corresponding pull-down current generation branch I0s; when it needs to provide an upward compensation voltage (which can also be referred to as a positive compensation voltage), it can close at least one second switch S2 to turn on the corresponding pull-up current generation branch IUs. In some scenarios, the compensation module 100 can also turn on at least part of the first switches S1 and at least part of the second switches S2 simultaneously to provide a superposition current with an appropriate change rate.

Optionally, the signal generation apparatus can further include a control module (not shown in the drawings), which can be connected to each first switch S1 and each second switch S2 to control the on/off status of each first switch S1 and each second switch S2 according to the compensation requirements of the power amplifier 300. The control module can be implemented using a low-power chip such as a microcomputer. Optionally, the control module can load a control program according to the compensation requirements of the power amplifier 300 in different time periods to control the on/off status of each first switch S1 and second switch S2 according to the control program. For example, if the output signal of the power amplifier 300 may increase in the first time period and requires downward compensation, the output signal is within an acceptable range in the second time period, the output signal may decrease in the third time period and requires upward compensation, and the output signal decreases more significantly in the fourth time period and requires a higher-magnitude upward compensation, at this time, the control module can turn on one pull-down current generation branch I0s in the first time period, turn off all first switches S1 and second switches S2 in the second time period, turn on one pull-up current generation branch IUs in the third time period, and continue to turn on another pull-up current generation branch IUs in the fourth time period (to provide a higher-magnitude upward compensation by turning on two pull-up current generation branches IUs).

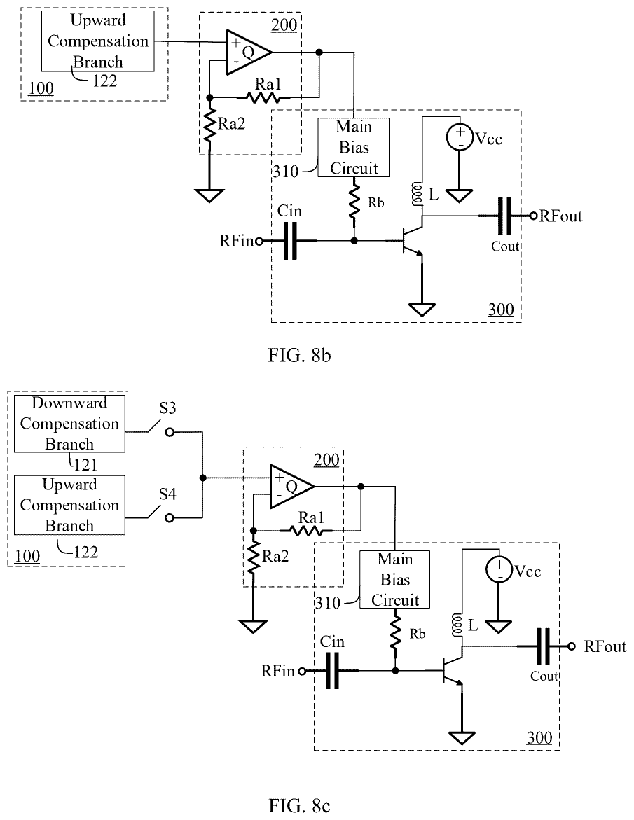

In some embodiments, as shown in FIGS. 8a and 8b, the compensation module 100 includes a downward compensation branch 121 and/or an upward compensation branch 122. Specifically, when the compensation module 100 includes both the downward compensation branch 121 and the upward compensation branch 122, each branch has a corresponding switch to control its activation.

The downward compensation branch 121 is configured to provide a first time-varying voltage that decreases over time. After being amplified by the signal amplification module 200, this first time-varying voltage can obtain a downward compensation voltage, which can compensate for an increase in the relevant signals within the power amplifier 300 over time.

The upward compensation branch 122 is configured to provide a second time-varying voltage that increases over time. After being amplified by the signal amplification module 200, this second time-varying voltage can obtain an upward compensation voltage, which can compensate for a decrease in relevant signals within the power amplifier 300 over time.

In some examples, as shown in FIG. 8c, the signal generation apparatus further includes a third switch S3 corresponding to the downward compensation branch 121 and a fourth switch S4 corresponding to the upward compensation branch 122. The third switch S3 is connected between an output terminal of the downward compensation branch 121 and an input terminal of the signal amplification module 200 to control the on/off status of the downward compensation branch 121. That is, the corresponding third switch S3 is closed when the downward compensation branch 121 needs to be turned on, and the corresponding third switch S3 is opened when the downward compensation branch 121 needs to be turned off. The fourth switch S4 is connected between an output terminal of the upward compensation branch 122 and the input terminal of the signal amplification module 200 to control the on/off status of the upward compensation branch 122. That is, the corresponding fourth switch S4 is closed when the upward compensation branch 122 needs to be turned on, and the corresponding fourth switch S4 is opened when the upward compensation branch 122 needs to be turned off.

Optionally, if the signal generation apparatus further includes a control module, the third switch S3 and the fourth switch S4 can be respectively connected to the control module, so that the control module can control the on/off status of the third switch S3 and the fourth switch S4 according to the compensation requirements of the power amplifier 300.

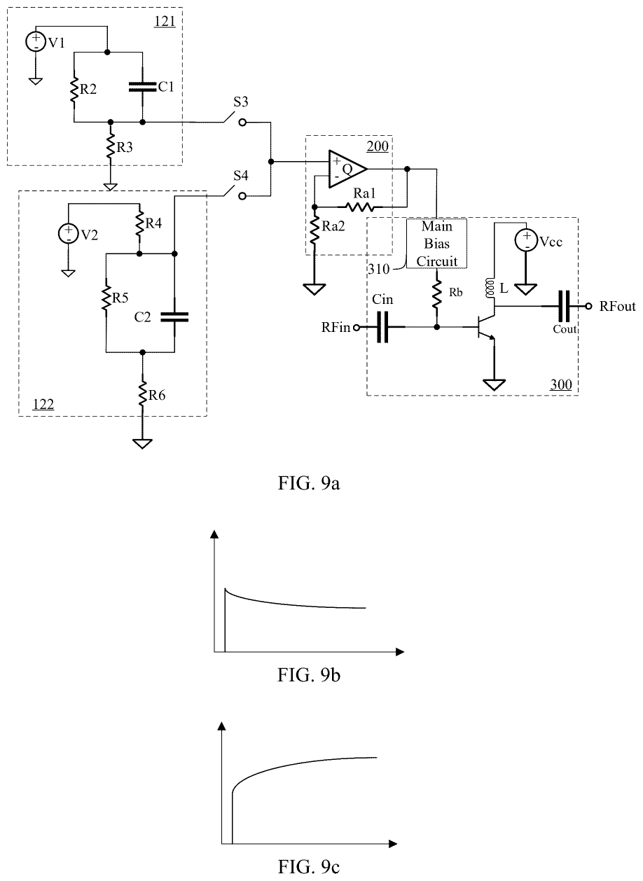

In some examples, as shown in FIG. 9a, the downward compensation branch 121 includes a first voltage source V1, a second resistor R2, a third resistor R3, and a first capacitor C1. A first terminal of the first voltage source V1 is connected to a ground terminal, and a second terminal is connected to a first terminal of the second resistor R2 and a first terminal of the first capacitor C1; a second terminal of the second resistor R2 serves as the output terminal of the downward compensation branch 121 and is respectively connected to the second terminal of the first capacitor C1, a first terminal of the third resistor R3, and the input terminal of the signal amplification module 200; a second terminal of the third resistor R3 is connected to the ground terminal. If the signal generation apparatus further includes the third switch S3, a second terminal of the second resistor R2 can be connected to the input terminal of the signal amplification module 200 through the third switch S3.

In the downward compensation branch 121, when the first voltage source V1 just starts to provide voltage, the voltage at the output terminal of the downward compensation branch 121 (i.e., the second terminal of the second resistor R2) is equal to the voltage provided by the first voltage source V1. Due to the charging effect of the first capacitor C1, the voltage at this output terminal gradually decreases and finally forms a stable voltage. The voltage change process at this output terminal can be referred to in FIG. 9b, which shows a first time-varying voltage that decreases over time.

Optionally, the first voltage source V1 can be controlled by an enable signal. For example, a control terminal of the first voltage source V1 can receive the enable signal. When the enable signal is at a high logic level, the first voltage source V1 provides the corresponding voltage; when the enable signal is at a low logic level, the first voltage source V1 does not provide voltage.

In some examples, as shown in FIG. 9a, the upward compensation branch 122 includes a second voltage source V2, a fourth resistor R4, a fifth resistor R5, a sixth resistor R6, and a second capacitor C2. A first terminal of the second voltage source V2 is connected to a ground terminal, and a second terminal of the second voltage source V2 is connected to a first terminal of the fourth resistor R4; a second terminal of the fourth resistor R4 serves as the output terminal of the upward compensation branch 122 and is connected to a first terminal of the fifth resistor R5, a first terminal of the second capacitor C2, and an input terminal of the signal amplification module 200; a second terminal of the fifth resistor R5 is respectively connected to a second terminal of the second capacitor C2 and a first terminal of the sixth resistor R6; a second terminal of the sixth resistor R6 is connected to the ground terminal. If the signal generation apparatus further includes a fourth switch S4, a second terminal of the fourth resistor R4 can be connected to the input terminal of the signal amplification module 200 through the fourth switch S4.

In the upward compensation branch 122, when the second voltage source V2 just starts to provide voltage, the voltage at the output terminal of the upward compensation branch 122 (i.e., the second terminal of the fourth resistor R4) is equal to the voltage at the first terminal of the sixth resistor R6. Due to the charging effect of the second capacitor C2, the voltage at this output terminal gradually increases and finally forms a stable voltage. The voltage change process at this output terminal can be referred to in FIG. 9c, which shows a second time-varying voltage that increases over time.

Optionally, the second voltage source V2 can be controlled by an enable signal. For example, a control terminal of the second voltage source V2 can receive the enable signal. When the enable signal is at a high logic level, the second voltage source V2 provides the corresponding voltage; when the enable signal is at a low logic level, the second voltage source V2 does not provide voltage.

In the signal generation apparatus, the compensation module 100 can provide at least one compensation signal based on possible variations in the output signal of the power amplifier 300 in corresponding application scenarios, so as to compensate the output signal of the power amplifier 300. The signal amplification module 200 amplifies the compensation signal, which then acts on the power amplifier 300. In this way, the compensation signal can counteract variations—arising over time and/or due to environmental factors—of relevant signals in the power amplifier 300, enabling the output signal of the power amplifier 300 to avoid being affected by environmental factors such as time and/or temperature, thus becoming more stable. Moreover, the compensation signal provided by the compensation module 100 can be determined based on the possible variations in the power amplifier 300 in corresponding application scenarios, and is independent of components such as the main bias circuit in the power amplifier 300, without the need to modify the internal structure and/or parameters of the power amplifier 300, and can be applied to the plurality of types of power amplifiers and various application scenarios, having higher flexibility.

It should be noted that in the aforementioned embodiments, when one terminal of a device is connected (or accessed) to an object, it can be a direct connection (or access) to the corresponding object. For example, when the input terminal of the reference current source I0 is used to receive the first voltage Vdd1, it can be a direct connection to the first voltage Vdd1. Alternatively, it can be an indirect connection (or access) to the corresponding object. For instance, when the input terminal of the reference current source I0 is used to receive the first voltage Vdd1, it can also be an indirect connection where the input terminal of the reference current source I0 receive the first voltage Vdd1 through other components. That is, the input terminal of the reference current source I0 is first connected to one terminal of a component, and the other terminal of that component is then connected to the first voltage Vdd1. The disclosure does not impose specific limitations in this regard.

The second aspect of the disclosure provides a signal generation method, which is applicable to the signal generation apparatus described in any of the aforementioned embodiments and includes steps S410 to S430.

S410 involves acquiring the compensation requirements of the power amplifier. This step S410 can involve performing analysis, such as testing the power amplifier in corresponding application scenarios, to acquire the variation characteristics of the power amplifier's output signal at different time intervals in such application scenarios, thereby determining the compensation requirements of the power amplifier. For example, in a certain application scenario, if the output signal of the power amplifier tends to increase during a first-time interval, the compensation requirement for the first time interval is downward compensation; if the output signal tends to decrease during a second time interval, the compensation requirement for the second time interval is upward compensation.

S420 involves providing at least one compensation signal based on the compensation requirements. Specifically, step S420 can provide compensation signals in different time intervals. For example, it can activate one pull-down current generation branch or one downward compensation branch during the first time interval to provide the downward compensation signal, activate one pull-up current generation branch or one upward compensation branch during the second time interval to provide the upward compensation signal, and activate two pull-down current generation branches during the third time interval to further increase the amplitude of the downward compensation signal, among other possibilities.

S430 involves amplifying the compensation signal so that the amplified compensation signal matches the power amplifier and can directly act on components such as the main bias circuit of the power amplifier. This enables the compensation signal to counteract variations—arising over time and/or due to environmental factors—of relevant signals in the power amplifier 300, preventing the output signal of the power amplifier from being affected by environmental factors such as time and/or temperature, and ensuring enhanced stability.

The aforementioned signal generation method, when applied to the signal generation apparatus described in any of the aforementioned embodiments, possesses all the beneficial effects of the signal generation apparatus described in those embodiments and will not be elaborated on further here.

The third aspect of the disclosure provides a power amplification system, which, as illustrated in figures such as FIG. 1 to FIG. 3, includes a power amplifier 300 and the signal generation apparatus described in any of the aforementioned embodiments.

Specifically, as shown in FIG. 2 and FIG. 3, the power amplifier 300 can include components such as a main bias circuit 310, a resistor Rb, an inductor L, a voltage source Vcc, a capacitor Cin, and a capacitor Cout, which are interconnected accordingly. Under the influence of the compensation signal output by the aforementioned signal generation apparatus, the power amplifier can be applied to various application scenarios and exhibit stable output signals, thereby offering higher reliability.

The aforementioned power amplifier incorporates the signal generation apparatus described in any of the aforementioned embodiments and possesses all the beneficial effects of the signal generation apparatus described in those embodiments, which will not be elaborated on further here.

Although the disclosure has been shown and described with respect to one or more implementations, those with skill in the art will appreciate, based on a reading and understanding of this specification and the accompanying drawings, equivalent variations and modifications. The disclosure includes all such modifications and variations and is limited only by the scope of the appended claims. In particular, regarding the various functions performed by the aforementioned components, the terms used to describe such components are intended to correspond to any component that performs the specified function of the described component (e.g., that is functionally equivalent), even though it is not structurally equivalent to the disclosed structure that performs the function in the exemplary implementations of this specification shown herein, unless otherwise indicated.

In other words, the above descriptions merely represent embodiments of the disclosure and do not limit its patent scope. All equivalent structures or equivalent process transformations made using the content of the disclosure's specification and drawings, such as the combination of technical features among different embodiments or the direct or indirect application in other related technical fields, are included within the patent protection scope of the disclosure.

Additionally, in the description of the disclosure, it should be understood that terms indicating orientation or positional relationships, such as “center,” “longitudinal,” “lateral,” “length,” “width,” “thickness,” “upper,” “lower,” “front,” “rear,” “left,” “right,” “vertical,” “horizontal,” “top,” “bottom,” “inner,” and “outer,” are based on the orientation or positional relationships shown in the accompanying drawings. These terms are used for the purpose of describing the disclosure and simplifying the description, rather than indicating or implying that the apparatus or element referred to must have a specific orientation or be constructed and operated in a specific orientation. Therefore, they should not be construed as limiting the disclosure. Furthermore, for structural elements with the same or similar characteristics, the disclosure may use the same or different reference numerals for identification. Moreover, terms such as “first” and “second” are used solely for descriptive purposes and should not be construed as indicating or implying relative importance or implicitly specifying the number of technical features indicated. Thus, features defined with “first” and “second” may explicitly or implicitly include one or more of those features. In the description of the disclosure, “plurality of” refers to two or more, unless otherwise explicitly and specifically defined.

In the disclosure, the term “exemplary” is used to mean “serving as an example, instance, or illustration.” Any embodiment described as “exemplary” in the disclosure is not necessarily to be construed as preferred or advantageous over other embodiments. To enable any person skilled in the art to make and use the disclosure, the disclosure provides the above description. In the foregoing description, various details are set forth for the purpose of explanation. It should be understood that those skilled in the art can recognize that the disclosure can be implemented without these specific details. In other embodiments, well-known structures and processes are not elaborated in detail to avoid unnecessary details obscuring the description of the disclosure. Therefore, the disclosure is not intended to be limited to the embodiments shown but is to be accorded the widest scope consistent with the principles and features disclosed herein.

1. A signal generation apparatus, comprising:
a compensation module, being independent of a main bias circuit in the power amplifier, the compensation module comprising:
a plurality of compensation branches, with each one respectively configured to output an upward compensation signal or a downward compensation signal; the output signals of these branches are combined to form a compensation signal that counteracts variations—arising over time and/or due to environmental factors—of relevant signals in the power amplifier; generation and combination of each compensation branch's output signals being determined based on the compensation requirements for possible variations in the power amplifier that may occur over time and/or due to environmental factors in corresponding application scenarios; and
a signal amplification module, being configured to amplify the compensation signal so that the amplified compensation signal matches the power amplifier and is directly output to the main bias circuit of the power amplifier.

2. The signal generation apparatus according to claim 1, wherein the compensation module comprises:
a reference current source, having an input terminal being configured to receive a first voltage, and an output terminal being connected to an input terminal of the signal amplification module, thus enabling the reference current source to generate a reference current;
at least one current providing unit, outputting a time-varying current in at least one direction to an output terminal of the reference current source, and the time-varying current being superimposed on the reference current to form a compensation current;

3. The signal generation apparatus according to claim 2, wherein the at least one current providing unit comprises:
a first current providing unit, providing a first superposition current to enable the corresponding compensation current to have a downward compensation capability; and/or
a second current providing unit, providing a second superposition current to enable the corresponding compensation current to have an upward compensation capability.

4. The signal generation apparatus according to claim 3, wherein the first current providing unit comprises at least one pull-up current generation branch; each pull-up current generation branch comprises:
a first current source;
a first variable capacitor,
a first variable resistor, and
a first MOS transistor,
wherein an input terminal of the first current source being configured to receive a second voltage and connected to a first terminal of the first variable resistor;
an output terminal of the first current source is respectively connected to a first terminal of the first variable capacitor and a gate of the first MOS transistor;
a second terminal of the first variable capacitor is connected to a ground terminal, a source of the first MOS transistor is connected to a second terminal of the first variable resistor, and a drain of the first MOS transistor is connected to the output terminal of the reference current source.

5. The signal generation apparatus according to claim 4, wherein the first current providing unit further comprises a first switch corresponding to each pull-up current generation branch; the first switch is connected between the drain of the first MOS transistor and the output terminal of the reference current source to control on/off status of the corresponding pull-up current generation branch.

6. The signal generation apparatus according to claim 3, wherein the second current providing unit comprises at least one pull-down current generation branch; each pull-down current generation branch comprises:
a second current source;
a second variable capacitor;
a second variable resistor;
a second MOS transistor;
a third MOS transistor; and
a fourth MOS transistor;
wherein an input terminal of the second current source is configured to receive a third voltage and is connected to a first terminal of the second variable resistor, and an output terminal of the second current source is respectively connected to a first terminal of the second variable capacitor and a gate of the second MOS transistor; a second terminal of the second variable capacitor is connected to the ground terminal; a drain of the second MOS transistor is respectively connected to a drain of the third MOS transistor, a gate of the third MOS transistor, and a gate of the fourth MOS transistor; a source of the third MOS transistor is connected to the ground terminal; a drain of the fourth MOS transistor is connected to the output terminal of the reference current source, and a source of the fourth MOS transistor is connected to the ground terminal.

7. The signal generation apparatus according to claim 6, wherein the second current providing unit further comprises a second switch corresponding to each pull-down current generation branches; the second switch is connected between the drain of the fourth MOS transistor and the output terminal of the reference current source to control on/off status of the corresponding pull-down current generation branch.

8. The signal generation apparatus according to claim 1, wherein the compensation module comprises a downward compensation branch and/or an upward compensation branch; the downward compensation branch is configured to provide a first time-varying voltage that decreases over time; the upward compensation branch is configured to provide a second time-varying voltage that increases over time.

9. The signal generation apparatus according to claim 8, further comprising:
a third switch corresponding to the downward compensation branch, the third switch being connected between an output terminal of the downward compensation branch and an input terminal of the signal amplification module to control on/off status of the downward compensation branch; and
a fourth switch corresponding to the upward compensation branch, being connected between an output terminal of the upward compensation branch and the input terminal of the signal amplification module to control on/off status of the upward compensation branch.

10. The signal generation apparatus according to claim 8, wherein the downward compensation branch comprises:
a first voltage source;
a second resistor;
a third resistor; and
a first capacitor;
wherein a first terminal of the first voltage source is connected to the ground terminal, and a second terminal of the first voltage source is connected to a first terminal of the second resistor and a first terminal of the first capacitor; a second terminal of the second resistor is connected to a second terminal of the first capacitor, a first terminal of the third resistor, and the input terminal of the signal amplification module; a second terminal of the third resistor is connected to the ground terminal.

11. The signal generation apparatus according to claim 8, wherein the upward compensation branch comprises:
a second voltage source;
a fourth resistor;
a fifth resistor;
a sixth resistor; and
a second capacitor;
wherein a first terminal of the second voltage source is connected to the ground terminal, and a second terminal of the second voltage source is connected to a first terminal of the fourth resistor; a second terminal of the fourth resistor is connected to a first terminal of the fifth resistor, a first terminal of the second capacitor, and the input terminal of the signal amplification module; a second terminal of the fifth resistor is connected to a second terminal of the second capacitor and a first terminal of the sixth resistor; a second terminal of the sixth resistor is connected to the ground terminal.

12. A signal generation method, being applied to the signal generation apparatus, the signal generation apparatus comprising a compensation module, being independent of a main bias circuit in the power amplifier, the compensation module comprising a plurality of compensation branches, with each one respectively configured to output an upward compensation signal or a downward compensation signal; wherein the signal generation method comprises:
obtaining compensation requirements for possible variations in the power amplifier that may occur over time and/or due to environmental factors in corresponding application scenarios;
controlling generation and combination of the output signals from respective compensation branches according to the compensation requirements to form a compensation signal; and
amplifying the compensation signal so that the amplified compensation signal matches the power amplifier.

13. The signal generation method according to claim 12, wherein the compensation module comprises:
a reference current source, having an input terminal being configured to receive a first voltage, and an output terminal being connected to an input terminal of the signal amplification module, thus enabling the reference current source to generate a reference current;
at least one current providing unit, outputting a time-varying current in at least one direction to an output terminal of the reference current source, and the time-varying current being superimposed on the reference current to form a compensation current;

14. The signal generation method according to claim 13, wherein the at least one current providing unit comprises:
a first current providing unit, providing a first superposition current to enable the corresponding compensation current to have a downward compensation capability; and/or
a second current providing unit, providing a second superposition current to enable the corresponding compensation current to have an upward compensation capability.

15. The signal generation method according to claim 12, wherein the compensation module comprises a downward compensation branch and/or an upward compensation branch; the downward compensation branch is configured to provide a first time-varying voltage that decreases over time; the upward compensation branch is configured to provide a second time-varying voltage that increases over time.

16. A power amplification system, comprising:
a power amplifier; and
a signal generation apparatus, comprising:
a compensation module, being independent of a main bias circuit in the power amplifier, the compensation module comprising:
a plurality of compensation branches, with each one respectively configured to output an upward compensation signal or a downward compensation signal; the output signals of these branches are combined to form a compensation signal that counteracts variations—arising over time and/or due to environmental factors—of relevant signals in the power amplifier; generation and combination of each compensation branch's output signals are determined based on the compensation requirements for possible variations in the power amplifier that may occur over time and/or due to environmental factors in corresponding application scenarios; and
a signal amplification module, being configured to amplify the compensation signal so that the amplified compensation signal matches the power amplifier and is directly output to the main bias circuit of the power amplifier.

17. The power amplification system according to claim 16, wherein the compensation module comprises:
a reference current source, having an input terminal being configured to receive a first voltage, and an output terminal being connected to an input terminal of the signal amplification module, thus enabling the reference current source to generate a reference current;
at least one current providing unit, outputting a time-varying current in at least one direction to an output terminal of the reference current source, and the time-varying current being superimposed on the reference current to form a compensation current;

18. The power amplification system according to claim 17, wherein the at least one current providing unit comprises:
a first current providing unit, providing a first superposition current to enable the corresponding compensation current to have a downward compensation capability; and/or
a second current providing unit, providing a second superposition current to enable the corresponding compensation current to have an upward compensation capability.

19. The power amplification system according to claim 18, wherein the first current providing unit comprises at least one pull-up current generation branch; each pull-up current generation branch comprises:
a first current source;
a first variable capacitor,
a first variable resistor, and
a first MOS transistor,
wherein an input terminal of the first current source being configured to receive a second voltage and a first terminal of the first variable resistor;
an output terminal of the first current source is respectively connected to a first terminal of the first variable capacitor and a gate of the first MOS transistor;
a second terminal of the first variable capacitor is connected to the ground terminal, a source of the first MOS transistor is connected to a second terminal of the first variable resistor, and a drain of the first MOS transistor is connected to the output terminal of the reference current source.

20. The power amplification system according to claim 16, wherein the compensation module includes a downward compensation branch and/or an upward compensation branch; the downward compensation branch is configured to provide a first time-varying voltage that decreases over time; the upward compensation branch is configured to provide a second time-varying voltage that increases over time.
